(19) United States
(12) Patent Application Publication
(10) Pub. No.: US 2014/0313674 A1
(43) Pub. Date: Oct. 23, 2014

(54) ELECTRONIC DEVICE WITH HEAT SINK

(71) Applicant: HON HAI PRECISION INDUSTRY CO., LTD., New Taipei (TW)

(72) Inventor: ZHI-BIN GUAN, New Taipei (TW)

(21) Appl. No.: 13/909,095

(22) Filed: Jun. 4, 2013

(30) Foreign Application Priority Data
Apr. 22, 2013 (TW) 102114209

(51) Int. Cl. H05K 7/20

(52) U.S. Cl. CPC H05K 7/20418
USPC 361/709

(57) ABSTRACT

An electronic device includes a circuit board, a first heat sink, a second heat sink, and two fixing members. The first heat sink includes a board and a number of fins extending from a top of the board. The second heat sink includes a connecting piece, two blocks mounted to opposite ends of the connecting piece, and a number of fins extending from a top of the connecting piece. The blocks are rested on the circuit board. Opposite ends of each fixing member are fixed to the board and one of the blocks. The first heat sink is mounted on the circuit board and maintains the second heat sink on the circuit board.

### BACKGROUND

1. Technical Field

The present disclosure relates to an electronic device including heat sinks.

2. Description of Related Art

Many electronic components, such as power supplies, are mounted on circuit boards adjacent to central processing units. Heat dissipation devices dissipating heat for the power supplies are all fixed to the motherboard with screws, which is time consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device, wherein the electronic device includes a first heat sink and a second heat sink.

FIG. 2 is an inverted view of the first and the second heat sinks of FIG. 1.

FIG. 3 is an assembled, isometric view of FIG. 1.

FIG. 4 is a cross-sectional view of FIG. 3, taken along the line IV-IV.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

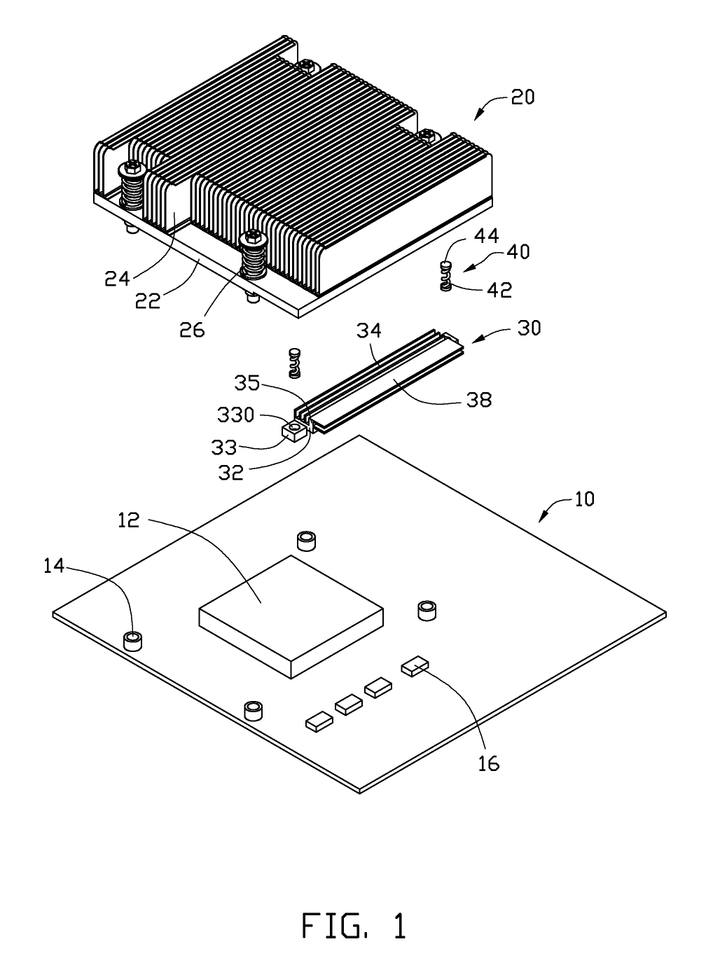

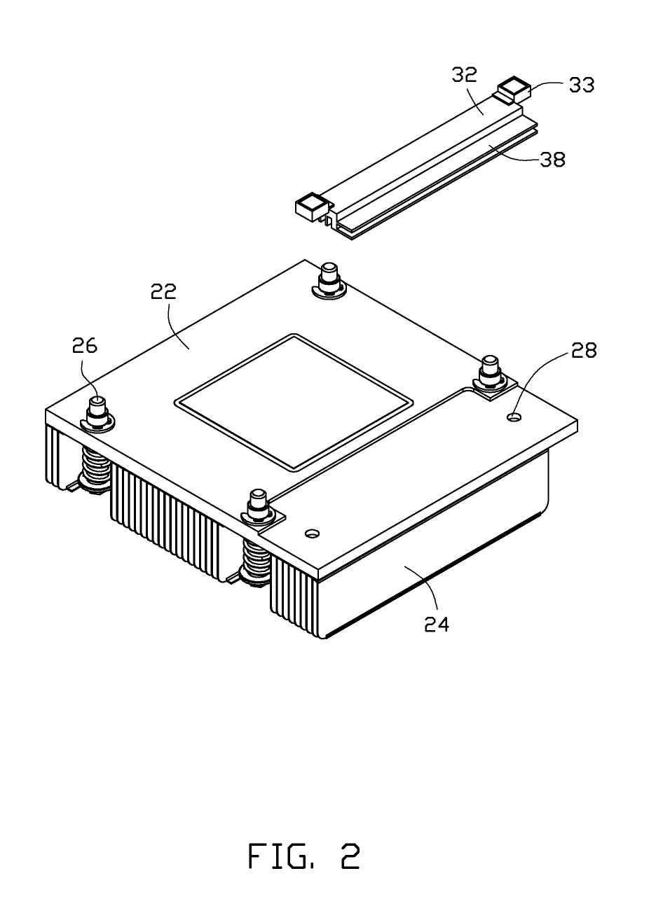

FIGS. 1 and 2 is an embodiment of an electronic device. The electronic device includes a circuit board 10, a first heat sink 20, a second heat sink 30, and two fixing members 40.

A central processing unit (CPU) 12 is mounted on the circuit board 10. Four posts 14 extend up from the circuit board 10, around the CPU 12. A row of electronic elements 16 is mounted on the circuit board 10, adjacent to the CPU 12. The electronic elements 16 are power supplies to supply voltage for the CPU 12.

The first heat sink 20 includes a rectangular board 22, a plurality of fins 24 perpendicularly extending up from the board 22, and four fasteners 26 mounted to four corners of the board 22. Two recesses 28 are defined in a bottom surface of the board 22 opposite to the fins 24.

The second heat sink 30 includes a first piece 32, two blocks 33 protrude from opposite ends of the first piece 32, and a second piece 35 perpendicularly extending up from a side of the first piece 32. Each block 33 defines a positioning hole 330 in a top surface. A plurality of fins 34 perpendicularly extending up from a top surface of the first piece 32, parallel to the second piece 35. A plurality of fins 38 perpendicularly extending out from an outer surface of the second piece 35 opposite to the fins 34.

Each fixing member 40 includes a resilient portion 42, two projections 44 connected to opposite ends of the resilient portion 42. The resilient portion 42 is a coil spring.

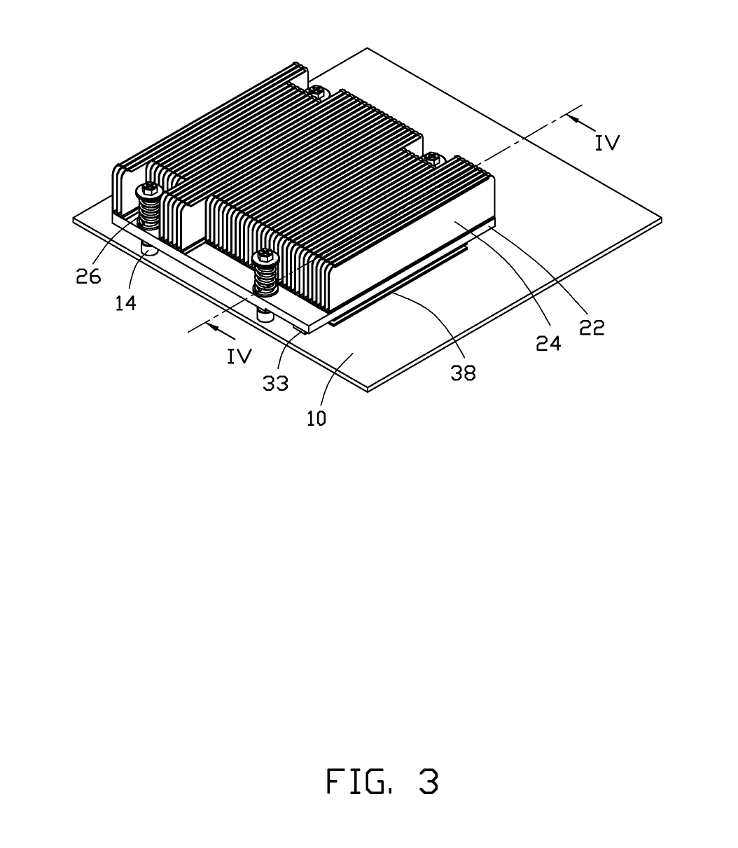

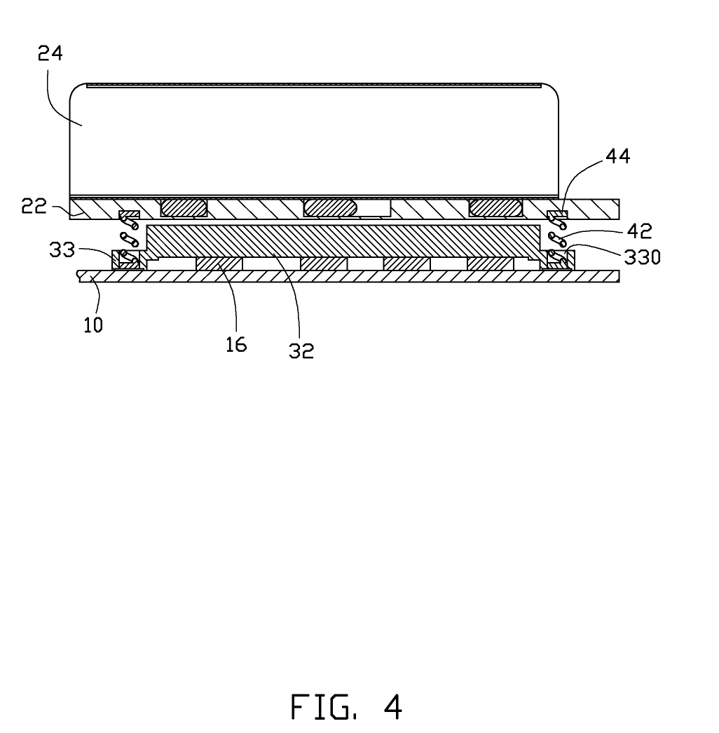

Referring to FIGS. 3 and 4, in assembly, the blocks 33 are rested on the circuit board 10, a bottom surface of the first piece 32 opposite to the fins 34 contacts tops of the electronic elements 16. The projections 44 of each fixing member 40 are received in one of the recesses 28 and one of the positioning holes 28. The fasteners 26 are engaged in the posts 14, to deform the resilient portions 42, until the board 22 is rested on the CPU 12, thereby fixing the first heat sink 20 and the second heat sink 30 to the circuit board 10. The first heat sink 20 maintains the second heat sink 30 on the circuit board 10 through the fixing members 40. The topmost fin 38 of the second heat sink 30 contacts the bottom surface of the board 22.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. An electronic device, comprising:
a circuit board;
a first heat sink comprising a board and a plurality of first fins extending from a top of the board;
a second heat sink comprising a first connecting piece, two blocks connected to opposite ends of the first connecting piece, and a plurality of second fins extending from a top of the connecting piece; and
two fixing members;
wherein the two blocks are rested on the circuit board, opposite ends of each fixing member are received respectively in the board of the first heat sink and in one of the two blocks; the first heat sink is mounted to the circuit board and maintains the second heat sink on the circuit board through the fixing members.

2. The electronic device of claim 1, wherein a plurality of posts is mounted on the circuit board, the first heat sink comprises a plurality of fasteners fastened to the plurality of posts.

3. The electronic device of claim 1, wherein a central processing unit (CPU) is formed on the circuit board among the plurality of posts, a row of electronic elements are mounted on the circuit board beside the CPU, the board of the first heat sink contacts a top of the CPU, the first connecting piece of the second heat sink contacts tops of the electronic elements.

4. The electronic device of claim 1, wherein the board of the first heat sink defines two recesses in a bottom surface of the board, each block defines a positioning hole in a top surface, opposite ends of each fixing member are received in one of the recesses and a corresponding one of the blocks.

5. The electronic device of claim 4, wherein each fixing member comprise a resilient portion and two projections connected to opposite ends of the resilient portion, the projections are received in one of the recesses and a corresponding one of the blocks, the resilient portion is deformed in response to the first heat sink being mounted to the circuit board.

6. The electronic device of claim 5, wherein the resilient portion is a coil spring.

7. The electronic device of claim 1, wherein the second heat sink further comprises a second connecting piece perpendicularly extending up from the first connecting piece and parallel to the plurality of second fins, a plurality of third fins perpendicularly extending from an outer surface of the second connecting piece opposite to the plurality of second fins.

8. The electronic device of claim 7, wherein topmost third fin extending from the second connecting piece contacts a bottom of the board of the first heat sink.
